(19) United States
(12) Patent Application Publication
(10) Pub. No.: US 2008/0290961 A1
(43) Pub. Date: Nov. 27, 2008

(54) SEMICONDUCTOR DEVICE

(75) Inventor: Katsura ABE, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC., Tokyo (JP)

(21) Appl. No.: 12/106,842

(22) Filed: Apr. 21, 2008

(30) Foreign Application Priority Data
Apr. 27, 2007 (JP) 2007-118911

(51) Int. Cl. H03H 7/38

(52) U.S. Cl. 333/32

(57) ABSTRACT

Disclosed is a semiconductor device including an input/output circuit having a terminal capacitance adjustment circuit connected to a signal line between an external pin and an initial-stage circuit; a command decoder for decoding an entered command and detecting a terminal capacitance adjustment command; and a terminal capacitance control circuit, which has a terminal capacitance adjustment register that holds information for controlling terminal capacitance, for controlling a capacitance value of the terminal capacitance adjustment circuit based upon the information in the terminal capacitance adjustment register. The information held by the terminal capacitance adjustment register is set based upon the output from the command decoder.

### REFERENCE TO RELATED APPLICATION

The present application is claiming the priority of the earlier Japanese patent application No. 2007-118911 filed on Apr. 27, 2007, the entire disclosure thereof being incorporated herein by reference thereto.

### FIELD OF THE INVENTION

This invention relates to a semiconductor device and, more particularly, to a semiconductor device in which it is possible to optimize the capacitance of input/output terminals even after the semiconductor device is assembled.

### BACKGROUND OF THE INVENTION

The operating frequency of semiconductor devices (semiconductor storage devices) and processors for controlling these semiconductor devices is rising. The data transfer rate between a semiconductor device (semiconductor storage device) and processor is also rising and the propagation time is becoming shorter.

If the operating frequency of a signal transmission bus between a semiconductor device (semiconductor storage device) and processor is raised, the influence of the impedance of the signal transmission bus and input/output terminals of the semiconductor device (semiconductor storage device) or input/output terminals of the processor grows.

It is required that the capacitance of input/output terminals of a semiconductor device (semiconductor storage device) connected to a signal transmission bus that operates at high frequency be adjusted to a value that is suited to the operating frequency.

If the capacitance of input/output terminals is too large, this leads to a delay in the propagation time of a control signal and data signal and causes a decline in the operating frequency of the system.

Conversely, if the capacitance of input/output terminals is too small, there is greater susceptibility to the influence of noise and this can lead to malfunction.

In actual semiconductor devices, there is the likelihood that input/output capacitance will vary from device to device owing to the manufacturing conditions.

For this reason, the semiconductor device is equipped with extra capacitance in order to adjust the terminal capacitance, and the terminal capacitance is optimized by changing the connections in an upper interconnect layer in the manufacture of the semiconductor device. An arrangement for adjusting terminal capacitance by changing the connections of wiring has been disclosed in Patent Document 1 (see FIG. 14 of Patent Document 1). Specifically, a switch (expressing the absence or presence of aluminum wiring) is provided between an external pin of the device and the gate of a MOS transistor having a grounded source and drain. If capacitance is added on, aluminum wiring is formed across the switch contacts using a wiring mask having wiring in which the switch contacts are in the closed state. If capacitance is not added on, the switch is placed in the open state by using a wiring mask that will not form aluminum wiring across the switch contacts.

As an example of a semiconductor device in which the capacitance of input/output terminals can be readily managed and adjusted, Patent Document 1 discloses an arrangement that includes a MOS transistor (MOS capacitance) having a gate connected to an external pin of the device as well as a source and drain tied together and connected to a bonding pad by aluminum wiring (the bonding pad being placed at a position where it is possible to perform bonding in a state in which a semiconductor integrated circuit has been mounted in the package). According to Patent Document 1, parasitic capacitance attached to the pad is reduced and a high-speed semiconductor device can be realized without providing switching means such as a switch, which relies upon the absence or presence of aluminum wiring, or a semiconductor switch, between an external pin of the device and the MOS transistor. Further, wiring by bonding wire for the connection to the bonding pad can be formed after the package is mounted. Patent Document 1 further discloses an arrangement including a fuse having a first end connected to the power supply or to ground, a resistor connected between the second end of the fuse and the power supply or ground, and an inverter having its input connected to the point at which the second end of the fuse and the resistor are connected, the output of the inverter being connected to drain and source of a MOS transistor.

Furthermore, as an example of an arrangement for controlling the terminal capacitance of a semiconductor device, Patent Document 2 discloses a semiconductor integrated circuit in which two terminal-capacitance adjusting elements (6a, 6b) formed by diffusion-layer capacitances are provided between a bonding pad and a protection resistance provided in a pre-stage of an input circuit, wherein terminal capacitance can be adjusted accurately without increasing chip size. In Patent Document 2, the disclosed arrangement includes resistors (9a, 9b, 9e) serially connected between the output of a negative potential generating circuit and ground; fuses (8a, 8d) connected in parallel with the resistors (9a, 9b), respectively; and fuses (8b, 8c) having first ends connected to one end of the resistor (9c) and to ground (GND), respectively, and having second ends tied together and connected to the terminal-capacitance adjusting element (6b) (see FIG. 1A of Patent Document 2).

Further, Patent Document 3 discloses a semiconductor device having an electrostatic protection transistor provided close to a pad, the device being adapted to make possible the control of unit capacitance of a semiconductor element, wherein the device has means for controlling the potential of a well in which the electrostatic protection transistor is formed. In Patent Document 3, the device has a changeover signal generator, a SUB potential changeover unit and a negative-voltage generator, wherein the output of the SUB potential changeover unit is connected to SUB of a well forming an ESD-element electrostatic protection transistor, the changeover signal generator has a series circuit comprising a resistor and a fuse provided between the output of the negative-voltage generator and ground, and the value of the output signal is set in accordance with whether or not the fuse has fused (see FIG. 9, etc., of Patent Document 3).

[Patent Document 1] Japanese Patent Kokai Publication No. JP-P2000-294735A

[Patent Document 2] Japanese Patent Kokai Publication No. JP-P2004-072104A

[Patent Document 3] Japanese Patent Kokai Publication No. JP-P2000-208707A

The following analysis is given by the present invention. The entire disclosures of the above mentioned Patent Documents 1 to 3 are herein incorporated by reference thereto.

In a case where terminal capacitance is adjusted by changing the connections of wiring in an upper-interconnect layer in the manufacture of a semiconductor storage device, it is necessary to change a photomask used in the manufacture of the semiconductor storage device. A problem which arises is higher cost.

The arrangement described in Patent Document 1 (in which a MOS capacitance is connected to a bonding pad), adjustment can be performed at the package assembly process (the bonding step) but cannot be carried out after packaging. The arrangement described in Patent Document 1 (namely the arrangement having the fuse), the fuse is blown in a wafer testing and capacitance cannot be adjusted after packaging.

Similarly, the arrangements described in Patent Documents 2 and 3, etc., seek optimization using fuses, etc., to adjust terminal capacitance. Although it is possible to reduce cost since there is no need for a photomask change, a problem is that adjustment can be performed only prior to packaging.

In order to reduce manufacturing cost and optimize device characteristics more simply, there is a need for means that make it possible to adjust terminal capacitance even after packaging (after shipping).

### SUMMARY OF THE DISCLOSURE

Accordingly, an object of the present invention is to provide a semiconductor device in which terminal capacitance can be adjusted even after packaging.

The above and other objects can be solved by the invention set forth below.

According to an aspect of the present invention, there is provided a semiconductor device comprising: a terminal capacitance adjustment circuit connected to a signal wiring between an external pin and an initial-stage circuit; a command decoder for decoding an entered command and detecting a terminal capacitance adjustment command; and a terminal capacitance control circuit, which includes a terminal capacitance adjustment register that holds information for controlling terminal capacitance, for controlling a capacitance value of the terminal capacitance adjustment circuit based upon the information in the terminal capacitance adjustment register; wherein the information held by the terminal capacitance adjustment register is set variably based upon an output from the command decoder.

In the present invention, the terminal capacitance adjustment circuit includes first and second MOS transistors of opposite conductivity types, wherein the first and second MOS transistors have respective gates connected in common to the signal wiring between the external pin and the initial-stage circuit, the first MOS transistor has a commonly connected source and drain supplied with a first control signal voltage from the terminal capacitance control circuit and the second MOS transistor has a commonly connected source and drain supplied with a second control signal voltage from the terminal capacitance control circuit; and the terminal capacitance control circuit has first and second driver circuits, which receive first and second information, respectively, held by the terminal capacitance adjustment register, for outputting first and second control signal voltages, respectively.

In the present invention, the terminal capacitance adjustment circuit includes first and second MOS transistors of opposite conductivity types, wherein the first and second MOS transistors have respective gates connected to the signal wiring between the external pin and the initial-stage circuit, the first MOS transistor has a commonly connected source and drain supplied with a first control signal voltage from the terminal capacitance control circuit and the second MOS transistor has a commonly connected source and drain supplied with a second control signal voltage from the terminal capacitance control circuit; and third and fourth MOS transistors of opposite conductivity types, wherein the third and fourth MOS transistors have respective gates connected to the signal wiring, the third MOS transistor has a commonly connected source and drain supplied with a third control signal voltage from the terminal capacitance control circuit and the fourth MOS transistor has a commonly connected source and drain supplied with a fourth control signal voltage from the terminal capacitance control circuit; and the terminal capacitance control circuit has first to fourth driver circuits, which receive first to fourth information, respectively, held by the terminal capacitance adjustment register, for outputting first and to fourth control signal voltages, respectively.

In the present invention, the semiconductor device further comprises a driver circuit in which at least one power supply voltage of high- and low-potential-side power supply voltages is set to a value different from those of the other driver circuits.

In the present invention, the terminal capacitance control circuit includes a plurality of terminal capacitance adjustment registers corresponding to respective ones of a plurality of external pins for adjusting terminal capacitance.

In the present invention, when a terminal capacitance adjustment command is detected by the command decoder, the value of a signal bit supplied to a predetermined external pin is made associated with information for controlling the terminal capacitance and is stored in the terminal capacitance adjustment register.

According to the present invention, in the terminal capacitance control circuit, a correspondence between the number of cycles of an input clock signal and an external pin, a terminal capacitance of which is to be adjusted is made, and a prescribed external pin is designated by the timing of a prescribed clock cycle.

According to the present invention, in the terminal capacitance control circuit, an external pin, a terminal capacitance of which is to be adjusted, is designated by an address signal received.

In the present invention, the terminal capacitance control circuit includes a counter for counting clock signals, and when the terminal capacitance adjustment command is detected by the command decoder, an external pin, a terminal capacitance of which is to be adjusted, is designated using the count value of the counter, and information for controlling the terminal capacitance is written to the terminal capacitance adjustment register corresponding to this external pin.

In the present invention, the initial-stage circuit is an input buffer or an input/output buffer.

The meritorious effects of the present invention are summarized as follows.

In accordance with the present invention, terminal capacitance can be adjusted even after packaging.

Still other features and advantages of the present invention will become readily apparent to those skilled in this art from the following detailed description in conjunction with the accompanying drawings wherein examples of the invention are shown and described, simply by way of illustration of the mode contemplated of carrying out this invention. As will be realized, the invention is capable of other and different examples, and its several details are capable of modifications in various obvious respects, all without departing from the invention. Accordingly, the drawing and description are to be regarded as illustrative in nature, and not as restrictive.

### BRIEF DESCRIPTIONS OF THE DRAWINGS

FIG. 1 is a diagram illustrating a first example of the present invention;

FIG. 2 is a diagram illustrating the configuration of a terminal capacitance adjustment circuit according to the first example;

FIG. 3 is a diagram illustrating the configuration of a terminal capacitance control circuit according to the first example;

FIG. 4 is a diagram illustrating the configuration of a terminal capacitance adjustment register according to the first example;

FIG. 5 is a diagram illustrating an example of a terminal capacitance adjustment circuit according to a modification of the first example;

FIG. 6 is a diagram illustrating the configuration of a terminal capacitance control circuit according to a modification of the first example;

FIG. 7 is a diagram illustrating the configuration of a terminal capacitance control circuit according to another modification of the first example;

FIG. 8 is a diagram illustrating an example of information in a case where terminal capacitance adjustment information of pins is designated in the first example;

FIG. 9 is a diagram illustrating to which pins terminal capacitance adjustment information in pin units is applied in the first example;

FIG. 10 is a diagram useful in describing a method of designating control information in a terminal capacitance adjustment register according to the first example;

FIG. 11 is a diagram illustrating the configuration of a second example of the present invention; and

FIG. 12 is a timing diagram useful in describing the operation of the second example.

### PREFERRED MODES OF THE INVENTION

Preferred modes of the present invention will now be described in detail with reference to the accompanying drawings.

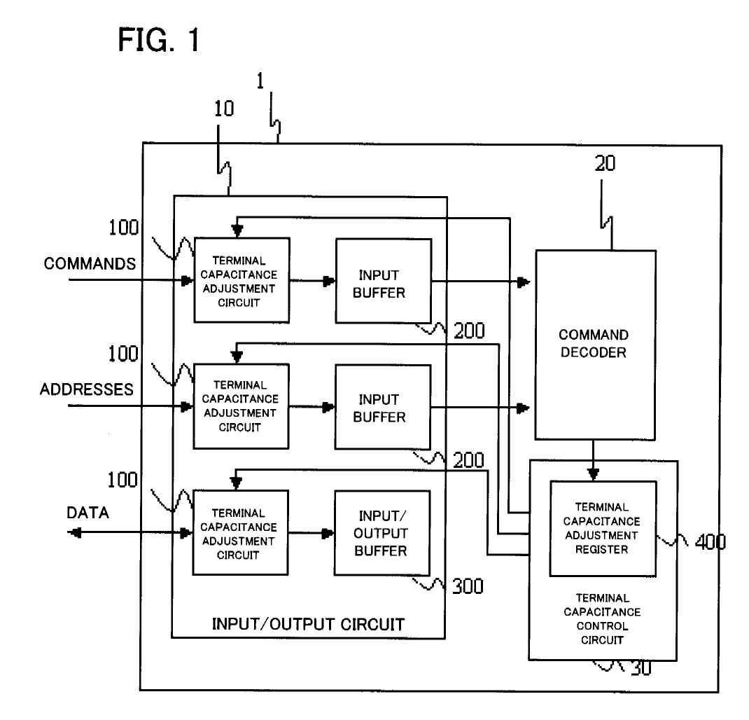

FIG. 1 is a diagram illustrating the configuration of a first example of the present invention. In FIG. 1, the principal components of a semiconductor device 1 according to the present invention are illustrated in block form. As shown in FIG. 1, the semiconductor device 1 includes an input/output circuit 10, a command decoder 20 and a terminal capacitance control circuit 30.

The input/output circuit 10 has a terminal capacitance adjustment circuit 100, an input buffer 200 for receiving a command or address, and an input/output buffer 300 for receiving and outputting data.

A plurality of the terminal capacitance adjustment circuits 100 are connected to the inputs of corresponding input buffers 200 and input/output buffer 300.

The terminal capacitance control circuit 30 includes a terminal capacitance adjustment register 400.

The command decoder 20 receives and decodes a command and sets information in the terminal capacitance adjustment register 400 of the terminal capacitance control circuit 30. On the basis of the information being held in the terminal capacitance adjustment register 400 of terminal capacitance control circuit 30, the terminal capacitance of the corresponding terminal capacitance adjustment circuit 100 is adjusted.

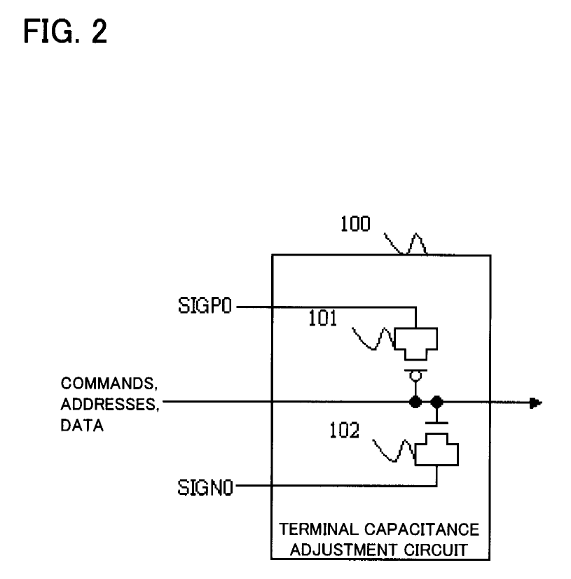

FIG. 2 is a diagram illustrating an example of the configuration of the terminal capacitance adjustment circuit 100 shown in FIG. 1. As shown in FIG. 2, the terminal capacitance adjustment circuit 100 includes a PMOS capacitance (PMOS transistor) 101 and an NMOS capacitance (NMOS transistor) 102 for adjusting terminal capacitance. A control signal SIGP0 is connected to commonly connected source and drain of the PMOS transistor 101, and a control signal SIGN0 is connected to the commonly connected source and drain of the NMOS transistor 102. The gate of the PMOS transistor 101 and the gate of the NMOS transistor 102 are connected in common to the applicable signal line among command, address and data lines. In order to adjust the input capacitance, the bias of the MOS gate capacitances is changed to the power supply level or ground level by the control signals SIGP0, SIGN0, thereby changing the input capacitance.

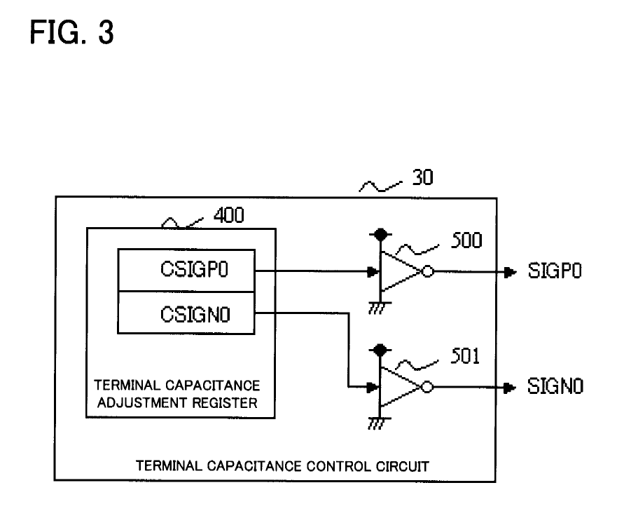

FIG. 3 is a diagram illustrating the configuration of the terminal capacitance control circuit 30 shown in FIG. 1. As shown in FIG. 3, the terminal capacitance control circuit 30 includes the terminal capacitance adjustment register 400, which holds information for adjusting terminal capacitance; a control signal generating circuit (driver) 500 for outputting the control signal SIGP0; and a control signal generating circuit (driver) 501 for outputting the control signal SIGN0. On the basis of information (CSIGP0, CSIGN0) held in the terminal capacitance adjustment register 400, the drivers 500 and 501 exercise control in such a manner that the potential at the source and drain of the PMOS transistor 101 or NMOS transistor 102 (FIG. 2) for adjusting terminal capacitance is changed to the power supply level or ground level.

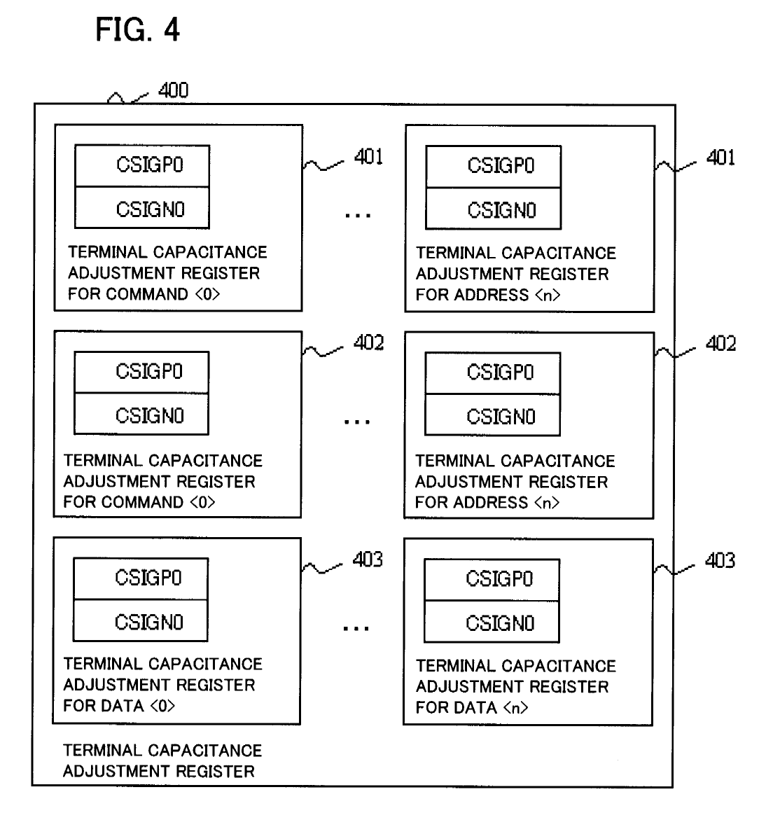

FIG. 4 is a diagram illustrating the configuration of the terminal capacitance adjustment register 400. The terminal capacitance adjustment register 400 includes a terminal capacitance adjustment register 401 for commands, a terminal capacitance adjustment register 402 for addresses and a terminal capacitance adjustment register 403 for data.

Information held in the terminal capacitance adjustment register 400 is provided for every pin of command, address and data pins, and it is possible to adjust input capacitance pin by pin. The terminal capacitance adjustment register 401 for commands (commands <0> to <n>) includes CSIGP0 and CSIGN0 as information for adjusting the terminal capacitance of command pins. The terminal capacitance adjustment register 402 for addresses (addresses <0> to <n>) includes CSIGP0 and CSIGN0 as information for adjusting the terminal capacitance of address pins. The terminal capacitance adjustment register 403 for data (data <0> to <n>) includes CSIGP0, CSIGN0 as information for adjusting the terminal capacitance of data pins.

The operation of the first example of the present invention will be described next. When a command, address or data is externally supplied to the semiconductor device, a control signal is supplied to the input buffer 200 or input/output buffer 300 through the terminal capacitance adjustment circuit 100. The information of the command, address or data then is transmitted to the internal circuitry. On the basis of the information being held in the terminal capacitance adjustment register 400 at this time, the terminal capacitance adjustment circuit 100 is controlled and input impedance is optimized.

In a case where a command which sets information for adjusting terminal capacitance enters, the command decoder 20 decodes the control information and writes the result to the terminal capacitance adjustment register 400 corresponding to the corresponding pin.

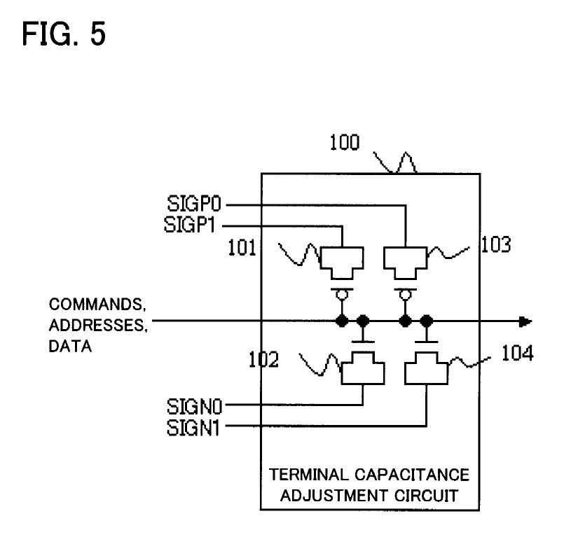

A modification of the first example of the present invention will be described next. As shown in FIG. 5, a plurality of PMOS transistors 101, 103 and a plurality of NMOS transistors 102, 104 are used in the terminal capacitance adjustment circuit 100. In this case, input capacitance can be adjusted more finely by changing control signals SIGP0, SIGP1, SIGN0 and SIGN1.

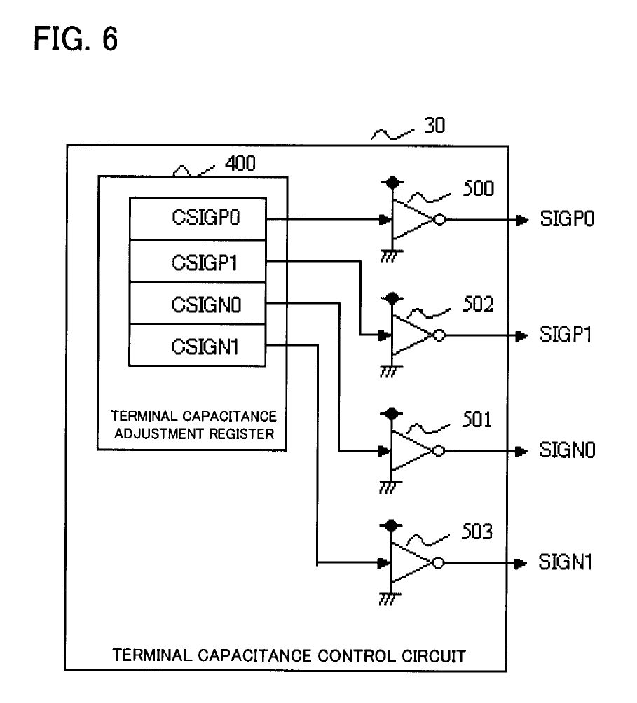

As illustrated in FIG. 6, the terminal capacitance control circuit 30 includes drivers 500, 502, 501 and 503 for generating control signals corresponding to the pairs of the plurality of PMOS transistors 101 and 103 and plurality of NMOS tran0sistors 102 and 104.

Furthermore, terminal capacitance adjustment registers are provided for every pin of command, address and data pins in a manner similar to the first example illustrated in FIG. 4. In this modification, however, each of the terminal capacitance adjustment registers 401 to 403 stores information CSIGP0, CSIGP1, CSIGN0 and CSIGN1 instead of CSIGP0 and CSIGN0.

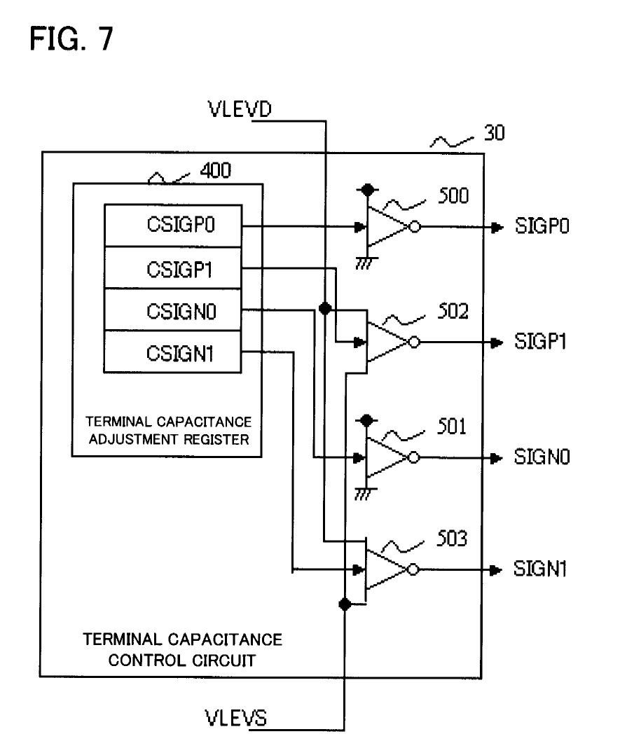

Next, the configuration of another modification of the first example will be described. In this modification, as illustrated in FIG. 7, the power supply levels of the drivers 502 and 503 in the terminal capacitance control circuit 30 are changed. The drivers 500, 501, which output SIGP0, SIGN0, respectively, are connected to the power supply and to ground.

The power supplies of the drivers 502 and 503 that output SIGP1 and SIGN1, respectively, are changed from the power supply level or ground level to any levels VLEVD and VLEVS and suitable levels are supplied to the terminal capacitance adjustment circuit 100, thereby making it possible to adjust terminal capacitance more finely.

Writing to the terminal capacitance adjustment register 400 by the command decoder 20 according to this example will now be described.

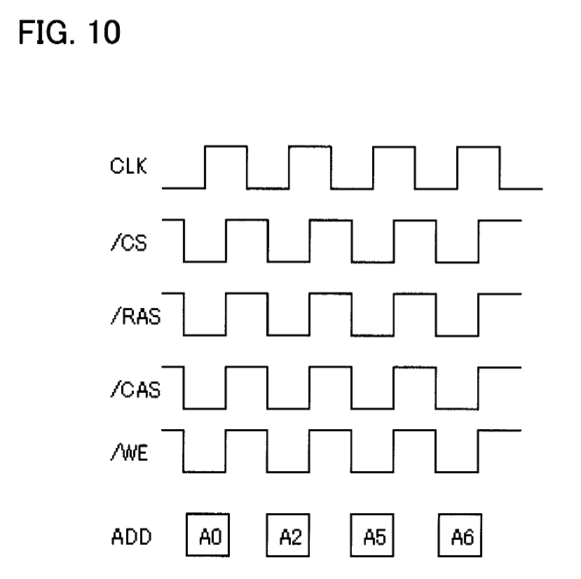

FIG. 10 is a diagram useful in describing a method of designating control information in the terminal capacitance adjustment register 400 that holds information (terminal capacitance adjustment information) necessary in order to adjust terminal capacitance.

In the case of a DRAM (dynamic random-access memory), command pins include those for chip select /CS, row address strobe /RAS, column address strobe /CAS and write enable /WE (where “/” represents active at the low level).

In this example, use is made of an example in which /CS=Low, /RAS=Low, /CAS=Low and /WE=Low, which are latched at the rising edge of a clock signal CLK. That is, an MRS (Mode Register Set) command is used.

The following items of information are designated:

terminal capacitance adjustment information of the pin of address A0 at the timing of the first rising edge of the clock signal CLK;

terminal capacitance adjustment information of the pin of address A2 at the timing of the second rising edge of the clock signal CLK;

terminal capacitance adjustment information of the pin of address A5 at the timing of the third rising edge of the clock signal CLK; and

terminal capacitance adjustment information of the pin of address A6 at the timing of the fourth rising edge of the clock signal CLK.

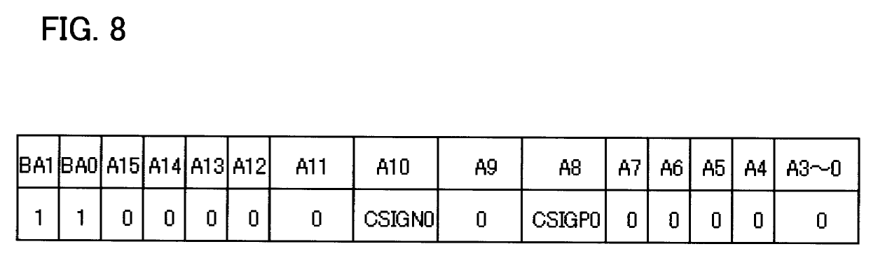

FIG. 8 illustrates an example of designation of terminal capacitance adjustment information of each pin shown in FIG. 10. As illustrated in FIG. 8, the designation of terminal capacitance adjustment information is performed by a combination of address signals A0 to A15 and bank addresses BA0, BA1 when an MRS command (/CS=Low, /RAS=Low, /CAS=Low, /WE=Low) is input.

The control information CSIGP0 for PMOS is set by the A8 pin, and the CSIGN0 for NMOS is set by the A10 pin.

For example, in a case where A8 is set to High and A10 is set to Low, then High and Low terminal capacitance adjustment information is held in CSIGP0 and CSIGN0, respectively, of the terminal capacitance adjustment register 400.

As a result, the output levels of the drivers 500 and 501 of terminal capacitance control circuit 30 become the power supply level and ground level, respectively. Accordingly, the source or drain of the PMOS transistor 101 and NMOS transistor 102 of terminal capacitance adjustment circuit 100 are supplied and terminal capacitance can be adjusted.

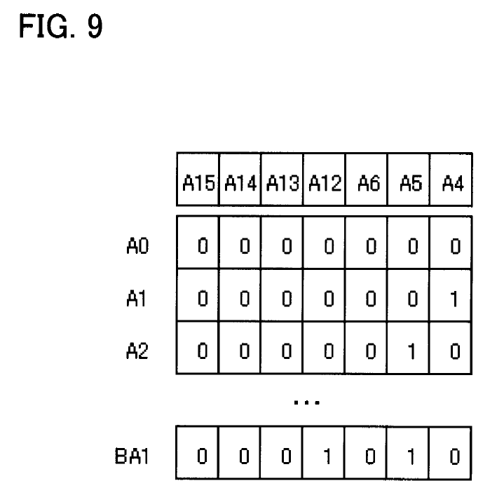

FIG. 9 is a diagram illustrating to which pins terminal capacitance adjustment information in pin units (FIG. 8) is applied. At the same time that A8 and A10 are designated, which pin terminal capacitance is adjusted is designated by the combination of pins A4, A5, A6, A12, A13, A14 and A15, as illustrated in FIG. 9, in case of the address pins.

In a case where the pin, terminal capacitance of which is to be adjusted is, e.g., the A2 pin, as shown in FIG. 9, it will suffice to input A4=0, A5=1, A6=0, A12=0, A13=0, A14=0 and A15=0, and designate terminal capacitance adjustment information CSIGP0 and CSIGN0 by A8 and A10.

FIG. 9 illustrates an example in which address pin A2 is used as the pin, terminal capacitance of which is to be adjusted. However, by defining pin designating information in one-to-one correspondence in FIG. 9, it is possible to adjust terminal capacitance with respect to each of the pins of command and data pins in addition to address pins.

The effects of this example will now be described.

In accordance with this example, it is possible to adjust the terminal capacitance of an input terminal or input/output terminal, even after packaging, by providing the command decoder 20, which is for decoding terminal capacitance adjustment information, and the terminal capacitance control circuit 30 for holding terminal capacitance adjustment information in accordance with the result of decoding by the command decoder 20 and controlling the terminal capacitance adjustment circuit 100.

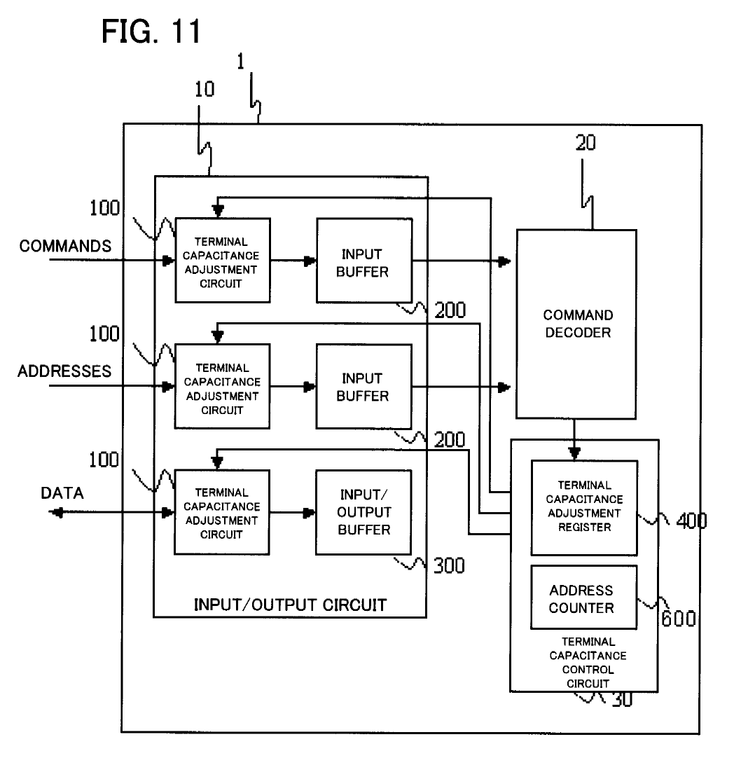

A second example of the present invention will be described next. FIG. 11 illustrates the configuration of the second example. In the first example, address pins for designating pins that adjust terminal capacitance are necessary, as shown in FIG. 9.

In the first example, if the total number of pins of address, command and data pins is 64, then a total of six (2⁶=64) address pins will be necessary in order to correlate terminal capacitance adjustment information pin by pin. The more the number of pins is increased, the greater the number of pins used in making designations.

In the second example of the present invention, as illustrated in FIG. 11, the terminal capacitance control circuit 30 includes the terminal capacitance adjustment register 400 and an address counter 600, the pin for performing adjustment of terminal capacitance is designated using the value of the count in the address counter 600, and terminal capacitance adjustment information is written to the terminal capacitance adjustment register 400 corresponding to this pin. In accordance with this example, it is unnecessary to designate a pin using an address signal, unlike the first example.

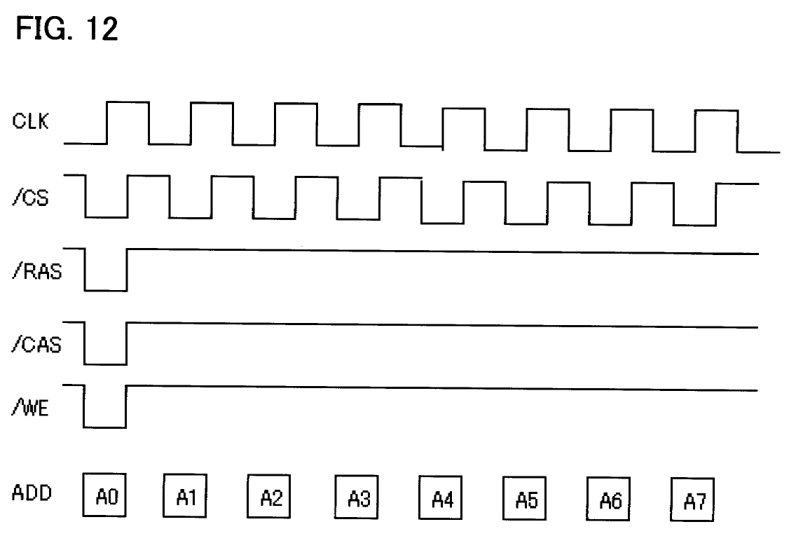

In this case, if a terminal capacitance adjustment command is input one time using the MRS command, then it is possible to input terminal capacitance adjustment information to the terminal capacitance adjustment register 400 successively, using the output of the address counter 600, in sync with the clock signal CLK from then onward. FIG. 12 is a timing chart useful in describing the operation of the second example. From the MRS command onward, terminal capacitance control information is input in a predetermined order at pins A0, A1, A2, A3, . . . , BA0, BA1, DQ0, DQ1 . . . DQ7, /RAS and /CAS, the count value from the address counter 600 that counts the clock signal CLK is used as an address, and terminal capacitance control information is held successively in the terminal capacitance adjustment register 402 for addresses (see FIG. 4), terminal capacitance adjustment register 403 for data and terminal capacitance adjustment register 401 for commands within the terminal capacitance adjustment registers 400 corresponding to the pins.

The present invention is suited for application to a DRAM (semiconductor storage device) or to a semiconductor device such as a controller or CPU.

Though the present invention has been described in accordance with the foregoing examples, the invention is not limited to these examples and it goes without saying that the invention covers various modifications and changes that would be obvious to those skilled in the art within the scope of the claims.

It should be noted that other objects, features and aspects of the present invention will become apparent in the entire disclosure and that modifications may be done without departing the gist and scope of the present invention as disclosed herein and claimed as appended herewith.

Also it should be noted that any combination of the disclosed and/or claimed elements, matters and/or items may fall under the modifications aforementioned.

What is claimed is:

1. A semiconductor device comprising:
a terminal capacitance adjustment circuit connected to a signal wiring provided between an external pin of the semiconductor device and an initial-stage circuit in the semiconductor device;
a command decoder that receives and decodes a command to detect a terminal capacitance adjustment command; and
a terminal capacitance control circuit including a terminal capacitance adjustment register that holds information for controlling terminal capacitance;
the terminal capacitance control circuit controlling a capacitance value of the terminal capacitance adjustment circuit based upon the information in the terminal capacitance adjustment register;
wherein the information held by the terminal capacitance adjustment register is set variably based upon an output from the command decoder.

2. The semiconductor device according to claim 1, wherein the terminal capacitance adjustment circuit includes
first and second MOS transistors of opposite conductivity types;
gates of the first and second MOS transistors being connected in common to the signal wiring between the external pin and the initial-stage circuit, a source and a drain of the first MOS transistor being coupled together and supplied with a first control signal voltage from the terminal capacitance control circuit, and a source and a drain of the second MOS transistor being coupled together and supplied with a second control signal voltage from the terminal capacitance control circuit; and wherein
the terminal capacitance control circuit includes
first and second driver circuits, which receive first and second information, respectively, held in the terminal capacitance adjustment register, and output the first and second control signal voltages, respectively.

3. The device according to claim 1, wherein the terminal capacitance adjustment circuit includes:
first and second MOS transistors of opposite conductivity types;
gates of the first and second MOS transistors being connected in common the signal wiring between the external pin and the initial-stage circuit, a source and a drain of the first MOS transistor being coupled together and supplied with a first control signal voltage from the terminal capacitance control circuit, and a source and a drain of the second MOS transistor being coupled together and supplied with a second control signal voltage from the terminal capacitance control circuit; and
third and fourth MOS transistors of opposite conductivity types;
gates of the third and fourth MOS transistors being connected in common to the signal wire, a source and a drain of the third MOS transistor being coupled together and supplied with a third control signal voltage from the terminal capacitance control circuit, and a source and a drain of the fourth MOS transistor being coupled together and supplied with a fourth control signal voltage from the terminal capacitance control circuit; and wherein
the terminal capacitance control circuit includes
first to fourth driver circuits, which receive first to fourth information, respectively, held in the terminal capacitance adjustment register, and outputs the first and to fourth control signal voltages, respectively.

4. The device according to claim 3, further comprising at least one driver circuit in which at least one or both of a high-potential-side power supply voltage and low-potential-side power supply voltage supplied to the driver circuits is set freely to a value different from those of the other driver circuits.

5. The device according to claim 1, wherein the terminal capacitance control circuit includes
a plurality of terminal capacitance adjustment registers corresponding to respective ones of a plurality of external pins for adjusting terminal capacitance.

6. The device according to claim 5, wherein when a terminal capacitance adjustment command is detected by the command decoder, the value of a signal bit supplied to a predetermined external pin is made associated with information for controlling the terminal capacitance and is stored in the terminal capacitance adjustment register.

7. The device according to claim 6, wherein the terminal capacitance control circuit makes a correspondence between number of cycles of an input clock signal and an external pin, a terminal capacitance of which is to be adjusted and designates a prescribed external pin by the timing of a prescribed clock cycle.

8. The device according to claim 6, wherein the terminal capacitance control circuit, designates an external pin, a terminal capacitance of which is to be adjusted based upon an address signal received.

9. The device according to claim 5, wherein the terminal capacitance control circuit includes a counter for counting a clock signal; and
wherein when a terminal capacitance adjustment command is detected by the command decoder, an external pin, a terminal capacitance of which is to be adjusted, is designated using a count value of the counter, and information for controlling the terminal capacitance is written to the terminal capacitance adjustment register corresponding to the external pin.

10. The device according to claim 1, wherein the initial-stage circuit is an input buffer or an input/output buffer.
